(19) United States
(12) Patent Application Publication
(10) Pub. No.: US 2011/0210432 A1
(43) Pub. Date: Sep. 1, 2011

(54) SEMICONDUCTOR DEVICE AND METHOD OF MANUFACTURING THE SAME

(75) Inventor: Yoshiaki GOTO, Aichi (JP)

(73) Assignee: KABUSHIKI KAISHA TOSHIBA, Tokyo (JP)

(21) Appl. No.: 13/025,526

(22) Filed: Feb. 11, 2011

(30) Foreign Application Priority Data
Mar. 1, 2010 (JP) 2010-044705

(51) Int. Cl. H01L 23/495; H01L 21/60

(52) U.S. Cl. 257/666; 438/109; 257/E21.506; 257/E23.052

(57) ABSTRACT

According to one embodiment, a semiconductor device includes: a lead group including a plurality of leads; a plurality of semiconductor memory chips stacked in a step shape on the lead group; and a resin mold section that seals the semiconductor memory chips. One end of a third lead and the other end of a second lead is connected by a metal wire for relay crossing over a first lead section included in the lead group. The metal wire for relay is provided in a space between the semiconductor memory chips stacked in the step shape and the lead group.

### CROSS-REFERENCE TO RELATED APPLICATIONS

This application is based upon and claims the benefit of priority from the prior Japanese Patent Application No. 2010-44705, filed on Mar. 1, 2010; the entire contents of which are incorporated herein by reference.

### FIELD

Embodiments described herein relate generally to a semiconductor device and method of manufacturing the semiconductor device.

### BACKGROUND

In the past, to realize a reduction in size and an increase in the density of packaging of a semiconductor device, a semiconductor package in which a plurality of semiconductor memory chips are stacked and sealed in one package has been used. As the semiconductor package, there is a semiconductor package employing a lead group including a plurality of leads, for example, a thin small outline package. In the semiconductor package employing a lead group, a plurality of semiconductor chips are stacked on the lead group and electrode pads formed on the semiconductor memory chips and the leads are electrically connected via metal wires.

In such a semiconductor package, because it is difficult to cross the leads in the package, the order of arrangement of inner leads and the order of arrangement of outer leads basically coincide with each other. Therefore, the order of arrangement of the electrode pads on the semiconductor memory chips needs to basically coincide with the order of arrangement of the outer leads as well. As a result, universality of the semiconductor memory chips is deteriorated. Therefore, the leads are connected by a metal wire for relay provided to cross over the lead between the leads. A technology for making it possible to change the order of arrangement of the electrode pads and the order of arrangement of the outer leads in this way is disclosed.

In recent years, from the viewpoint of, for example, a reduction in manufacturing cost, in some case, a plurality of semiconductor memory chips are stacked in a step shape. When the semiconductor chips are stacked in the step shape, a planar space larger than a planar shape of one semiconductor memory chip is necessary in a package. Therefore, when the semiconductor memory chips are stacked in the step shape, it is difficult to two-dimensionally secure a space for providing metal wires for relay and the chip size of the semiconductor memory chips is limited.

### BRIEF DESCRIPTION OF THE DRAWINGS

FIG. 1 is a plan view of the external appearance of a semiconductor device;

FIG. 2 is a sectional view along line A-A of the semiconductor device shown in FIG. 1;

FIG. 3 is a plan view of a lead group;

FIG. 4 is a diagram of the lead group viewed from the lower surface side, wherein a state in which semiconductor memory chips are stacked is shown;

FIG. 5 is a schematic diagram of a positional relation among first to third leads;

FIG. 6 is a partially enlarged view of a section B shown in FIG. 2;

FIG. 7 is a flowchart for explaining a procedure of a method of manufacturing the semiconductor device; and

FIG. 8 is a flowchart for explaining a modification of the procedure of the method of manufacturing the semiconductor device.

### DETAILED DESCRIPTION

In general, according to one embodiment, a semiconductor device includes: a lead group including a plurality of leads; a plurality of semiconductor memory chips stacked in a step shape on the lead group; and a resin mold section that seals the semiconductor memory chips. The lead group includes: a first lead extending from the inside to the outside of the resin mold section; a second lead arranged on one side of the first lead on the inside of the resin mold section; and a third lead extending from the inside to the outside of the resin mold section and arranged on the other side of the first lead. The semiconductor device further includes: a first metal wire that electrically connects the first lead and electrode pads of the semiconductor memory chips on the inside of the resin mold section; a second metal wire that electrically connects the second lead and the electrode pads of the semiconductor memory chips on the inside of the resin mold section; and a metal wire for relay that electrically connects the third lead and the second lead crossing over the first lead on the inside of the resin mold section. The metal wire for relay is provided in a space between the semiconductor memory chips stacked in the step shape and the lead group.

Exemplary embodiments of a semiconductor device and a method of manufacturing the semiconductor device will be explained below in detail with reference to the accompanying drawings. The present invention is not limited to the following embodiments.

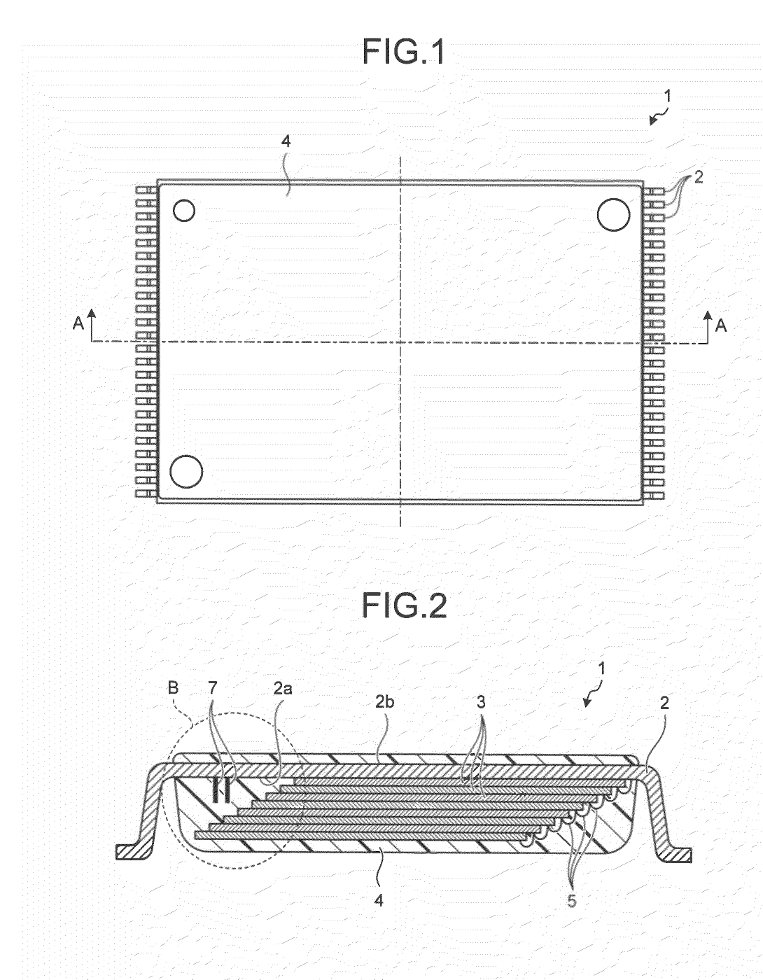

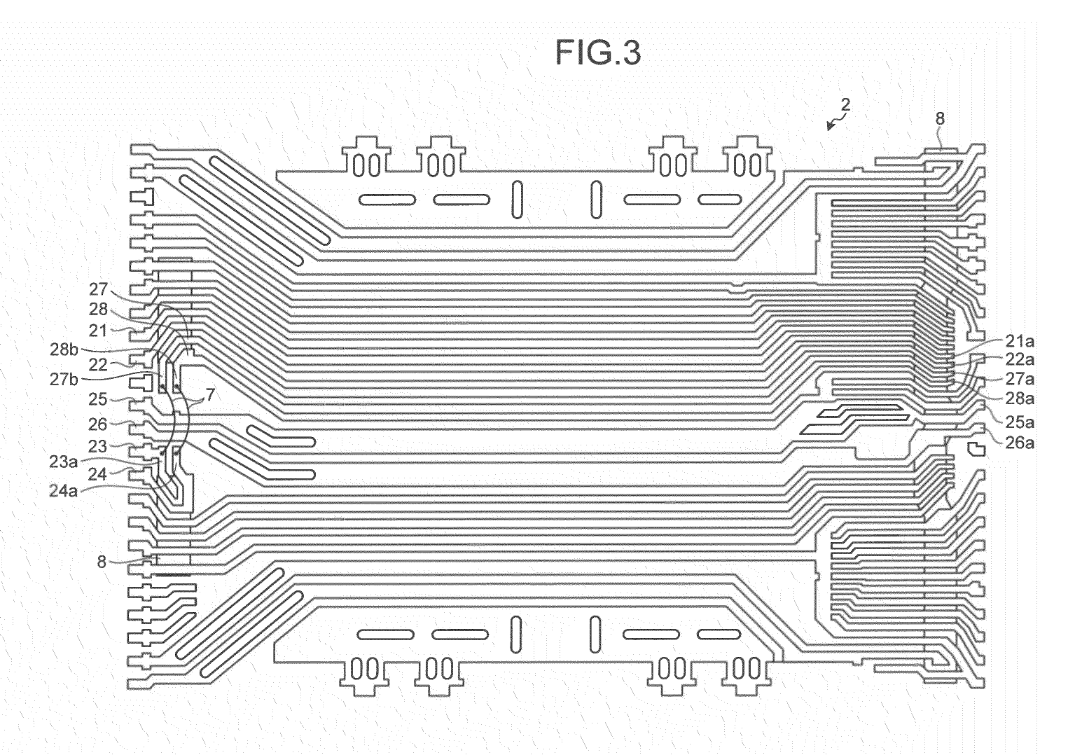

FIG. 1 is a plan view of the external appearance of a semiconductor device (semiconductor package) according to a first embodiment. FIG. 2 is a sectional view along line A-A of the semiconductor device shown in FIG. 1. FIG. 3 is a plan view of a lead group.

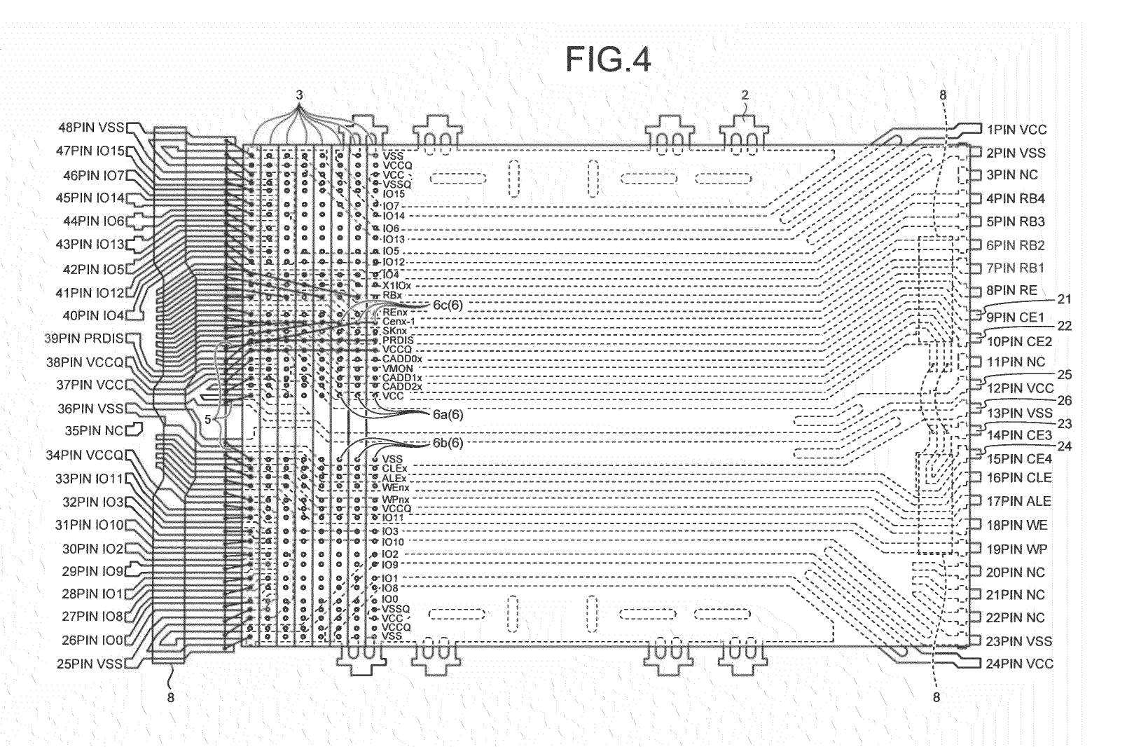

A semiconductor package (semiconductor device) 1 includes a lead group 2, a semiconductor memory chip 3, and a resin mold section 4. The lead group 2 functions as a circuit base material for mounting elements. A plurality of the semiconductor memory chips 3 are stacked on a lower surface 2a side of the lead group 2. FIG. 4 is diagram of the lead group 2 viewed from the lower surface 2a side. A state in which the semiconductor memory chips 3 are stacked is shown in FIG. 4. When a state in which the semiconductor package 1 is mounted on a mounting board is taken as a reference, a surface opposed to the mounting board is represented as lower surface 2a of the lead group 2 and a surface on the opposite side of the surface opposed to the mounting board is represented as upper surface 2b of the lead group 2.

The semiconductor package 1 is formed by sealing both the surfaces of the lead group 2 with a resin mold section 4 made of a resin material. The resin mold section 4 forms an outer shell of the semiconductor package 1. The resin mold section 4 is formed at height for completely covering the semiconductor memory chips 3. The resin mold section 4 is formed by covering, with a mold, the lead group 2 mounted with mounted components such as the semiconductor memory chips 3 and injecting a softened resin material into the mold.

As shown in FIG. 3, the lead group 2 includes a plurality of leads including a lead for first chip enable (CE) 21, a lead for second CE 22, a lead for third CE 23 (a third lead), a lead for fourth CE 24 (a third lead), a lead for power supply 25 (a first lead), a lead for ground 26 (a first lead), a lead for third CE relay 27 (a second lead), and a lead for fourth CE relay 28 (a second lead). The lead group 2 is formed of metal and includes iron or copper as a main material.

The leads are fixed by an insulative fixing tape 8 (a fixing member) to prevent a positional shift from occurring. Specifically, at least one of the lead for first CE 21, the lead for second CE 22, the lead for third CE 23, the lead for fourth CE 24, the lead for power supply 25, and the lead for ground 26 (in FIG. 4, the lead for first CE 21, the lead for second CE 22, the lead for power supply 25, and the lead for ground 26) and the lead for third CE relay 27 and the lead for fourth CE relay 28 are fixed by the fixing tape 8.

In the following explanation, in the lead group 2 including the leads 21 to 28, a section exposed to the outer side of the resin mold section 4 is referred to as outer lead section and a section sealed on the inner side of the resin mold section 4 is referred to as inner lead section. The outer lead section functions as an outer connection terminal of the semiconductor package 1. The lead group 2 is formed to further extend to both the sides than that shown in FIGS. 3 and 4. In other words, most of the outer lead section is not shown in FIGS. 3 and 4.

Among the leads 21 to 28, the leads 21 to 26 other than the lead for third CE relay 27 and the lead for fourth CE relay 28 are formed to extend from the inside to the outer side of the resin mold section 4 and include the outer lead section and the inner lead section. The lead for third CE relay 27 and the lead for fourth CE relay 28 need not to exposed to the outside of the resin mold section 4 and enough to include only the inner lead section. The order of arrangement of the leads 21 to 26 including the outer lead section is set according to, for example, specifications of the mounting board on which the semiconductor package 1 is mounted. The leads 21 to 26 in this embodiment are arranged in order of the lead for first CE 21, the lead for second CE 22, the lead for power supply 25, the lead for ground 26, the lead for third CE 23, and the lead for fourth CE 24 along a direction from 1PIN to 24PIN. The inner lead section mainly functions as a connecting section for electrode pads 6 of the semiconductor memory chips 3.

The semiconductor memory chip 3 is a storage element such as a NAND flash memory. On the side of one side of the semiconductor memory chip 3, a plurality of the electrode pads 6 are formed to be arranged along the one side. A plurality of the semiconductor memory chips 3 are stacked on the lower surface 2a side of the lead group 2. The semiconductor memory chip 3 in the bottom layer (the nearest layer to the lead group 2) among the semiconductor memory chips 3 is bonded to the lead group 2 by a bonding material. As the bonding material, a thermosetting or photo-curable die attach film (an adhesive film) containing general polyimide resin, epoxy resin, acrylic resin, or the like as a main component is used.

The other semiconductor memory chips 3 are bonded in a step shape on the semiconductor memory chip 3 in the bottom layer bonded on the lead group 2, whereby the semiconductor memory chips 3 are stacked. The die attach film is also used for bonding of the semiconductor memory chips 3. In this embodiment, eight semiconductor memory chips are stacked. The number of the semiconductor memory chips 3 to be stacked only has to be plural and is not limited to eight. The electrode pads 6 provided on the side of one sides of the semiconductor memory chips 3 can be exposed by stacking the semiconductor memory chips 3 in the step shape. The exposed electrode pads 6 are electrically connected to the lead group 2 using metal wires 5 (first metal wires) (second metal wires) such as Au wires. The semiconductor memory chips 3 are not limited to the NAND flash memories and can be, for example, a stacked product of the NAND flash memories and controller elements for the NAND flash memories.

As shown in FIG. 4, the electrode pads 6 of the semiconductor memory chips 3 include power supply voltage electrode pads 6a (VCC), electrode pads for ground 6b (VSS), and electrode pads for chip enable (CE) 6c (CEnx). The order of arrangement of the pads 6a to 6c is set according to specifications of the semiconductor chips 3. The pads 6a to 6c in this embodiment are arranged in order of the electrode pads for CE 6c, the power supply voltage electrode pads 6a, and the electrode pads for ground 6b along a direction from 1PIN to 24PIN.

Among the stacked semiconductor memory chips 3, the electrode pads for CE 6c formed on the first and second semiconductor memory chips 3 counted from the bottom layer (the layer directly bonded to the lead group 2) need to be electrically connected to the lead for first CE 21. The electrode pads for CE 6c formed on the third and fourth semiconductor memory chips 3 counted from the bottom layer need to be electrically connected to the lead for second CE 22. The electrode pads for CE 6c formed on the fifth and sixth semiconductor memory chips 3 counted from the bottom layer need to be electrically connected to the lead for third CE 23. The electrode pads for CE 6c formed on the seventh and eighth semiconductor memory chips 3 counted from the bottom layer need to be electrically connected to the lead for fourth CE 24.

However, the order of arrangement of the electrode pads 6 formed on the semiconductor memory chips 3 and the order of arrangement of the leads 21 to 26 on the lead group 2 side are different. Therefore, if the leads 21 to 26 are directly drawn around to the outer lead section, the electrode pads 6 and the leads 21 to 26 cannot be connected in the correspondence relation explained above. It is difficult to cross the leads in the package.

Therefore, in this embodiment, the electrode pads 6 and the leads 21 to 26 are connected in the correspondence relation using the lead for third CE relay 27, the lead for fourth CE relay 28, and metal wires for relay 7.

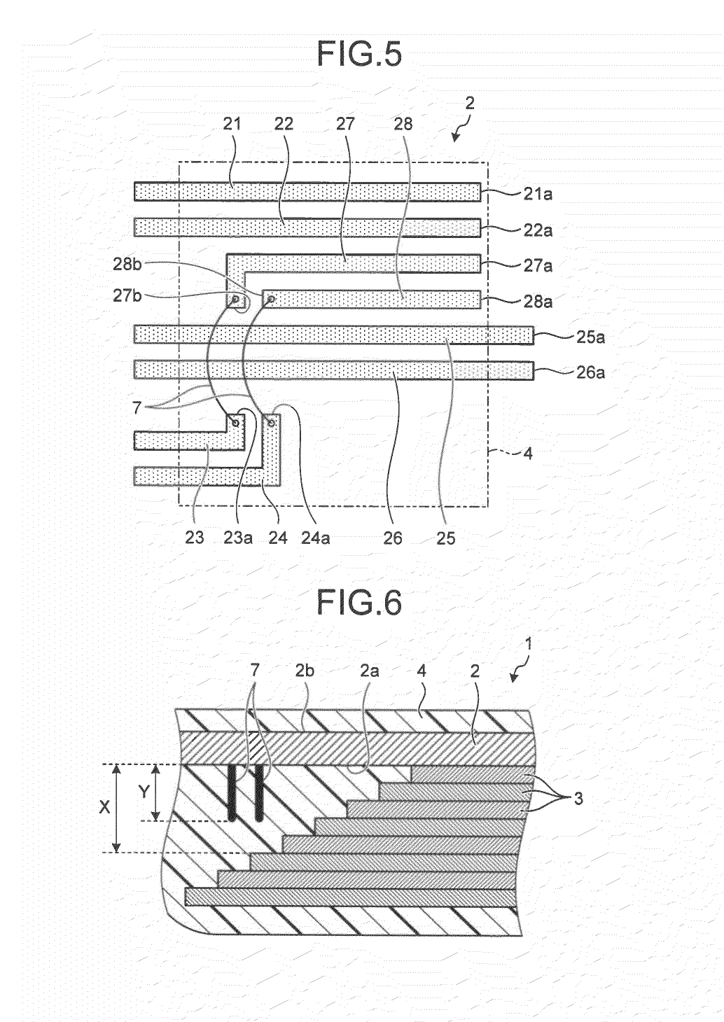

More specifically, as shown in FIG. 5, the leads 21 to 28 are arranged in order of the lead for first CE 21, the lead for second CE 22, the lead for third CE relay 27, the lead for fourth CE relay 28, the lead for power supply 25, the lead for ground 26, the lead for third CE 23, and the lead for fourth CE 24 along a direction from 1PIN to 24PIN. In other words, the second leads 27 and 28 are arranged on one side of the first leads 25 and 26 (on the side of the lead for first CE 21 and the lead for second CE 22) and the third leads 23 and 24 are arranged on the other side of the first leads 25 and 26 to two-dimensionally hold the first leads between the second leads and the third leads.

The electrode pads for CE 6c of the first and second semiconductor memory chips 3 counted from the bottom layer and one end 21a of the lead for first CE 21 are electrically connected by the meal wires 5. The electrode pads for CE 6c of the third and fourth semiconductor memory chips 3 counted from the bottom layer and one end 22a of the lead for second CE 22 are electrically connected by the metal wires 5.

The electrode pads for CE 6c of the fifth and sixth semiconductor memory chips 3 counted from the bottom layer are electrically connected to one end 27a of the lead for third CE relay 27 rather than the lead for third CE 23 by the metal wires 5 (the second metal wires). The electrode pads for CE 6c of the seventh and eighth semiconductor memory chips 3 counted from the bottom layer are electrically connected to one end 28a of the lead for fourth CE relay 28 rather than the lead for fourth CE 24 by the metal wires 5 (the second metal wires).

The power supply voltage electrode pad 6a of the first semiconductor memory chip 3 counted from the bottom layer and one end 25a of the lead for power supply 25 are electrically connected by the metal wire 5 (the first metal wire). The electrode pad for ground 6b of the first semiconductor memory chip 3 counted from the bottom layer and one end 26a of the lead for ground 26 are connected by the metal wire 5 (the first metal wire).

The other end 27b of the lead for third CE relay 27 and one end 23a of the lead for third CE 23 are electrically connected by the metal wire for relay 7. The other end 28b of the lead for fourth CE relay 28 and one end 24a of the lead for fourth CE 24 are electrically connected by the metal wire for relay 7. The metal wires for relay 7 are provided to cross over the lead for power supply 25 and the lead for ground 26. By adopting such a configuration, even if the order of arrangement of the electrode pads 6a to 6c and the order of arrangement of the leads 21 to 26 are different, it is possible to electrically connect the electrode pads 6a to 6c and the leads 21 to 26 in an appropriate correspondence relation.

As shown in FIG. 2 the metal wires for relay 7 are provided in a space between the semiconductor memory chips 3 stacked in the step shape and the lead group 2. By adopting such a configuration, it is possible to superimpose, in a two-dimensional relation, a region where the semiconductor memory chips 3 are stacked and a region where the metal wires for relay 7 are provided. Because the semiconductor memory chips 3 are stacked in the step shape, a planar space larger than a planar shape of one semiconductor memory chip 3 is necessary in the package. On the other hand, if the metal wires for relay 7 are provided in the space between the semiconductor memory chips 3 stacked in the step shape and the lead group 2, a two-dimensional region for only stacking at least the semiconductor memory chips 3 is secured in the package. Therefore, a two-dimensional special space for providing the metal wires for relay 7 is unnecessary. Therefore, it is easy to secure a space for providing the metal wires for relay 7 and the chip size of the semiconductor memory chips 3 is less easily limited.

FIG. 6 is a partially enlarged view of a section B shown in FIG. 2. In this embodiment, the thickness of the semiconductor memory chip 3 is about 50 micrometers and the thickness of a die attach film for bonding the semiconductor memory chip 3 is about 10 micrometers. The wire length of the metal wire for relay 7 is about 1.44 millimeters and wire loop height Y is about 140 micrometers. The metal wires for relay 7 are provided in a space between the sixth semiconductor memory chip 3 counted from the bottom layer and the lead group 2 and a space between the seventh semiconductor memory chip 3 counted from the bottom layer and the lead group 2. An interval X between the sixth semiconductor memory chip 3 counted from the bottom layer and the lead group 2 is X=(50+10)×5=300 micrometers. Then, an interval between the metal wires for relay 7 and the semiconductor memory chips 3 is at least X−Y=300−140=160 micrometers. Therefore, a sufficient margin can be secured.

In this embodiment, the order of arrangement of the lead for third CE 23 and the lead for fourth CE 24 is changed. However, the present invention is not limited to this. The order of arrangement of various leads can be changed according to, for example, the specifications of the mounting board on which the semiconductor package 1 is mounted. This makes it unnecessary to prepare the semiconductor memory chips 3 for each of the specifications of the mounting board. Therefore, it is possible to improve universality of the semiconductor memory chips 3 and contribute to a reduction in manufacturing cost of the semiconductor package 1.

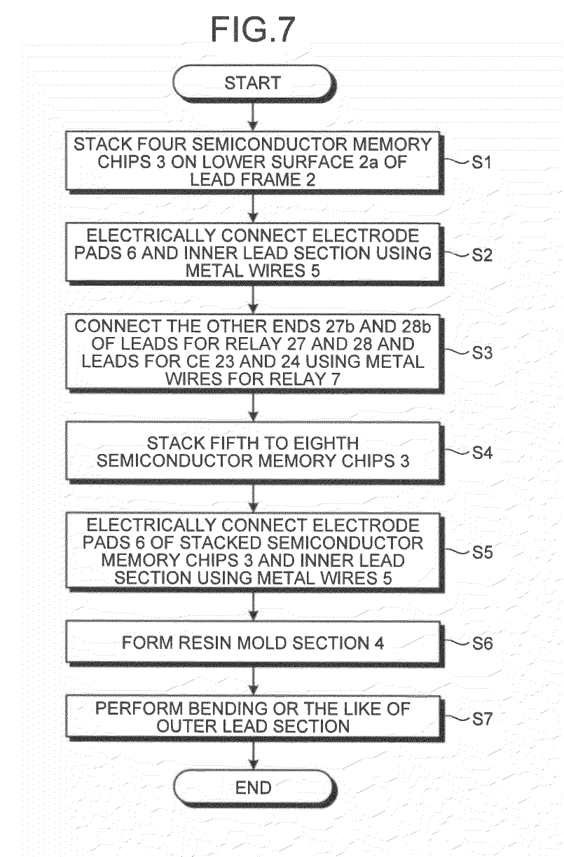

A method of manufacturing the semiconductor package 1 is explained below. FIG. 7 is a flowchart for explaining a procedure of the method of manufacturing the semiconductor package 1. First, four semiconductor memory chips 3 are stacked on the bottom surface 2a of the lead group 2 (step S1). Subsequently, the electrode pads 6 of the stacked semiconductor memory chips 3 and the inner lead section of the lead group 2 are electrically connected by the metal wires 5 (step S2). The process of step S2 includes a process for connecting, using the metal wires 5, the one ends 21a and 22a of the leads for CE 21 and 22 and the electrode pads for CE 6c of the stacked semiconductor memory chips 3, a process for connecting, using the metal wire 5, the one end 25a of the lead for power supply 25 and the power supply voltage electrode pad 6a, and a process for connecting, using the metal wire 5, the lead for ground 26 and the electrode pad for ground 6b. The other ends 27b and 28b of the leads for CE relay 27 and 28 and the leads for CE 23 and 24 are connected by the metal wires for relay 7 (step S3). The order of step S2 and step S3 can be opposite.

The fifth to eighth semiconductor memory chips 3 are stacked (step S4). The electrode pads 6 formed on the semiconductor memory chips 3 and the inner lead section of the lead group 2 are electrically connected by the metal wires 5 (step S5). The process of step S5 includes a process for connecting, using the metal wires 5, the one ends 27a and 28a of the leads for CE relay 27 and 28 and the electrodes for CE 6c of the stacked semiconductor memory chips 3. The resin mold section 4 is formed (step S6). Bending or the like of the outer lead section is performed (step S7). According to the processes explained above, the semiconductor package 1 is manufactured. In the manufacturing process for the semiconductor package 1, the lead group 2 is held by a frame member (not shown) integrally formed around the lead group 2. The frame member and the lead group 2 are also collectively referred to as lead frame. In general, the processes of steps S1 to S6 are performed in a state of the lead frame. In the process for performing the bending or the like at step S7, cutoff of the frame member from the lead frame is also performed.

In the manufacturing method explained with reference to FIG. 7, the connection of the metal wires for relay 7 is performed after a part of the semiconductor memory chips 3 are stacked. Because the leads as a part of the lead group 2 are fixed by the semiconductor memory chips 3, occurrence of a deficiency due to deformation of the metal wires for relay 7 is suppressed.

In a wire bonder that bonds the metal wires 5 and 7, in some case, there is a limit in the number of stacked layers of the semiconductor memory chips 3 that can be bonded at a time. In this case, the stacking of the semiconductor memory chips 3 and the bonding of the electrode pads 6 are performed a plurality of times. For example, when a wire bonder that can bond maximum four stacked layers of the semiconductor memory chips 3 at a time is used, the bonding to the electrode pads 6 is performed twice. In this case, if the metal wires for relay 7 are bonded before the semiconductor memory chips 3 are stacked, the bonding process is performed three times in total including the bonding of the metal wires 5 to the electrode pads 6.

On the other hand, in the manufacturing method explained with reference to FIG. 7, the bonding between the second leads 27 and 28 and the third leads 23 and 24 and the bonding of the semiconductor memory chip 3 stacked first to the electrode pad 6 are performed at a time at steps S2 to S3. Therefore, the bonding process only has to be performed twice including bonding performed after the remaining semiconductor chips 3 are stacked. This makes it possible to reduce the number of times of bonding in the manufacturing process for the semiconductor package 1 and contribute to improvement of manufacturing efficiency.

If all the semiconductor memory chips 3 are stacked, the region where the metal wires for relay 7 are provided is covered with the semiconductor memory chips 3. Therefore, it is difficult to perform work by a general-purpose wire bonder. Because of deterioration in workability, a bonding failure and the like tend to occur. Therefore, the bonding of the metal wires for relay 7 is desirably performed at a stage when a part of the semiconductor memory chips 3 are stacked.

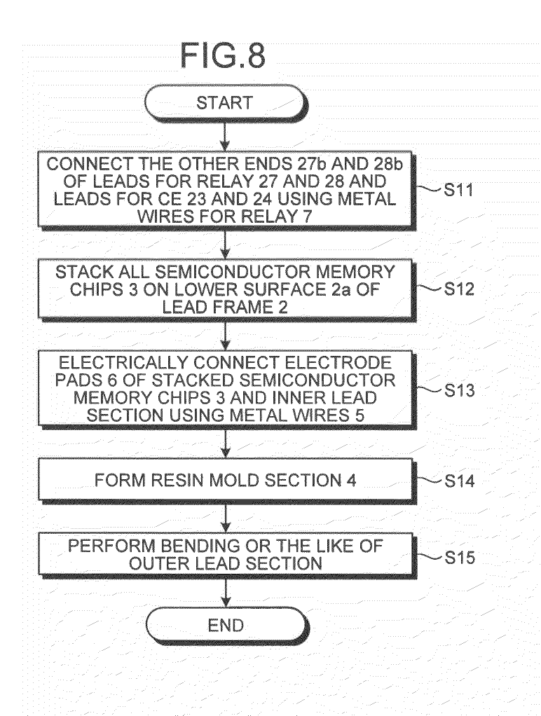

A modification of the method of manufacturing the semiconductor package 1 is explained below. FIG. 8 is a flowchart for explaining a modification of the procedure of the method of manufacturing the semiconductor package 1. First, the other ends 27b and 28b of the leads for relay 27 and 28 and the leads for CE 23 and 24 are connected by the metal wires for relay 7 (step S11). Subsequently, all the (eight) semiconductor memory chips 3 are stacked on the lower surface 2a of the lead group 2 (step S12). The electrode pads 6 of the stacked semiconductor memory chips 3 and the inner lead section of the lead group 2 are electrically connected by the metal wires 5 (step S13). The resin mold section 4 is formed (step S14). Bending or the like of the outer lead section is performed (step S15). According to the processes explained above, the semiconductor package 1 is manufactured.

In the manufacturing method according to the modification, a wire bonder that can collectively perform bonding for the stacked eight semiconductor memory chips 3 is used. In this case, because the process for stacking the semiconductor memory chips 3 only has to be performed once, it is possible to contribute to improvement of manufacturing efficiency of the semiconductor package 1. Because the metal wires for relay 7 are bonded before the semiconductor memory chips 3 are stacked, the bonding can be smoothly performed without being obstructed by the semiconductor memory chips 3 that cover the region where the metal wires for relay 7 are provided. This makes it possible to suppress occurrence of a deficiency such as a bonding failure.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A semiconductor device comprising:
a lead group including a plurality of leads;
a plurality of semiconductor memory chips stacked in a step shape on the lead group; and
a resin mold section that seals the semiconductor memory chips, wherein
the lead group includes:
a first lead extending from an inside to an outside of the resin mold section;
a second lead arranged on one side of the first lead on the inside of the resin mold section; and
a third lead extending from the inside to the outside of the resin mold section and arranged on the other side of the first lead, wherein
the semiconductor device further comprises:
a first metal wire that electrically connects one end of the first lead and electrode pads of the semiconductor memory chips on the inside of the resin mold section;
a second metal wire that electrically connect one end of the second lead and the electrode pads of the semiconductor memory chips on the inside of the resin mold section; and
a metal wire for relay that electrically connects one end of the third lead and the other end of the second lead crossing over the first lead on the inside of the resin mold section, and
the metal wire for relay is provided in a space between a part of the semiconductor memory chips stacked in the step shape and the lead group.

2. The semiconductor device according to claim 1, wherein the first lead is a lead for power supply.

3. The semiconductor device according to claim 1, wherein the first lead is a lead for ground.

4. The semiconductor device according to claim 1, wherein the third lead is a lead for chip enable.

5. The semiconductor device according to claim 1, further comprising an insulative fixing member that fixes the second lead to at least one of the first lead and the third lead.

6. The semiconductor device according to claim 1, wherein the semiconductor memory chips are NAND flash memories.

7. The semiconductor device according to claim 1, wherein the semiconductor memory chips are stacked by being bonded by a bonding film.

8. A method of manufacturing a semiconductor device comprising:
stacking, in a step shape, a plurality of memory chips on a lead group including: a first lead extending from an inside to an outside of a resin mold section; a second lead arranged on one side of the first lead on the inside of the resin mold section; and a third lead extending from the inside to the outside of the resin mold section and arranged on the other side of the first lead;
electrically connecting, using a first metal wire, one end of the first lead and electrode pads of the semiconductor memory chips;
electrically connecting, using a second metal wire, one end of the second lead and the electrode pads of the semiconductor memory chips; and
electrically connecting, using a metal wire for relay, one end of the third lead and the other end of the second lead crossing over the first lead, wherein
the metal wire for relay is provided in a space between a part of the semiconductor memory chips stacked in the step shape and the lead group.

9. The method of manufacturing a semiconductor device according to claim 8, further comprising forming the resin mold section to cover a part of the first lead, the second lead, a part of the third lead, and the semiconductor memory chips.

10. The method of manufacturing a semiconductor device according to claim 8, wherein the first lead is a lead for power supply.

11. The method of manufacturing a semiconductor device according to claim 8, wherein the first lead is a lead for ground.

12. The method of manufacturing a semiconductor device according to claim 8, wherein the third lead is a lead for chip enable.

13. The method of manufacturing a semiconductor device according to claim 8, further comprising fixing, using an insulative fixing member, the second lead to at least one of the first lead and the third lead.

14. The method of manufacturing a semiconductor device according to claim 8, wherein the semiconductor memory chips are NAND flash memories.

15. The method of manufacturing a semiconductor device according to claim 8, wherein the stacking of the semiconductor memory chips is performed by bonding using a bonding film.

16. The method of manufacturing a semiconductor device according to claim 8, further comprising stacking, after performing connection of the first metal wire and the metal wire for relay in a state in which a part of the semiconductor memory chips are stacked, the other semiconductor memory chips.

17. The method of manufacturing a semiconductor device according to claim 16, wherein the metal wire for relay is provided in a space between the other semiconductor memory chips stacked later and the lead group.

18. The method of manufacturing a semiconductor device according to claim 8, further comprising stacking the semiconductor memory chips after performing connection of the metal wire for relay.

19. The method of manufacturing a semiconductor device according to claim 8, further comprising performing connection of the first metal wire and the second metal wire after stacking all the semiconductor memory chips.
